(19) United States
(12) Patent Application Publication
(10) Pub. No.: US 2026/0020139 A1
(43) Pub. Date: Jan. 15, 2026

(54) OPTICAL MODULE

(71) Applicant: HISENSE BROADBAND MULTIMEDIA TECHNOLOGIES CO., LTD., Qingdao (CN)

(72) Inventors: Jiaao ZHANG, Qingdao (CN); Xinnan WANG, Qingdao (CN); Jianwei MU, Qingdao (CN); Lin YU, Qingdao (CN)

(21) Appl. No.: 19/331,474

(22) Filed: Sep. 17, 2025

Related U.S. Application Data
(63) Continuation of application No. PCT/CN2023/118986, filed on Sep. 15, 2023.

(30) Foreign Application Priority Data
Mar. 31, 2023 (CN) 202310341598.X
Mar. 31, 2023 (CN) 202320697214.3
Mar. 31, 2023 (CN) 202320702794.0

(51) Int. Cl. H05K 1/02; G02B 6/42

(52) U.S. Cl. CPC H05K 1/0207; G02B 6/4272; G02B 6/428; H05K 1/0206; H05K 1/021; H05K 2201/10121; H05K 2203/041

(57) ABSTRACT

An optical module, wherein a digital signal processor is connected to a circuit board via solder balls. The circuit board includes an upper layer board, at least one thermally conductive plate and a lower layer board. A thermally conductive layer is plated on the upper layer board and contacts lower side plates of a lower shell part of the optical module. Ground solder balls at an edge of the digital signal processor are connected to the thermally conductive layer. A thermally conductive connecting block is disposed in the upper layer board. Ground solder balls at an inner side of the digital signal processor are connected to the ground solder balls through the thermally conductive connecting block. A thermally conductive via hole is provided between the upper layer board and the thermally conductive plate to transfer heat from the digital signal processor to the thermally conductive plate.

This disclosure is a continuation of International Application No. PCT/CN2023/118986, filed on Sep. 15, 2023, which claims priority to Chinese Patent Application No. 202310341598.X, filed with the China National Intellectual Property Administration on Mar. 31, 2023, to Chinese Patent Application No. 202320702794.0, filed with the China National Intellectual Property Administration on Mar. 31, 2023, and to Chinese Patent Application No. 202320697214.3, filed with the China National Intellectual Property Administration on Mar. 31, 2023. All above-mentioned applications are hereby incorporated by reference in their entirety.

### FIELD OF THE INVENTION

The present disclosure relates to the field of optical communication technology, and in particular, to an optical module.

### BACKGROUND OF THE INVENTION

In new services and application models such as cloud computing, mobile Internet, and video, optical communication technology is widely used. In optical communication, the optical module is a device that enables the conversion between optical and electrical signals, and it is one of the key devices in optical communication equipment.

Optical module typically includes optoelectronic devices such as a laser and a digital signal processor (DSP). During operation, the optoelectronic devices generate heat, leading to a temperature rise in the optical module. However, when the optoelectronic devices are in a high-temperature environment, their performance is comprised. Therefore, heat dissipation is essential in the optical module.

### SUMMARY OF THE INVENTION

The present disclosure provides an optical module, including: a lower shell part, a circuit board, and a digital signal processor, the lower shell part including a bottom plate and two lower side plates, the two lower side plates being connected to respective opposing sides of the bottom plate; the circuit board being mounted in the lower shell part, two opposite sides of the circuit board respectively contacting the two lower side plates; and the digital signal processor being electrically connected to the circuit board via solder balls arranged in a rectangular array, the solder balls including ground solder balls and power solder balls; where the circuit board includes an upper layer board, at least one thermally conductive plate, and a lower layer board which are arranged in a stacked manner, a thermally conductive layer being plated on the upper layer board, the thermally conductive layer contacting the lower side plates, and ground solder balls located at an edge of the digital signal processor being connected to the thermally conductive layer; a thermally conductive connecting block being disposed in the upper layer board, ground solder balls located at an inner side of the digital signal processor being electrically connected to the ground solder balls located at the edge of the digital signal processor through the thermally conductive connecting block, and the thermally conductive connecting block not extending across entire solder ball region of the digital signal processor; an area of the at least one thermally conductive plate being larger than an area of the digital signal processor, and a side of the at least one thermally conductive plate contacting corresponding lower side plate; and a thermally conductive via hole being provided between the upper layer board and the at least one thermally conductive plate, two ends of the thermally conductive via hole being respectively connected to the ground solder balls and the at least one thermally conductive plate, such that heat from the digital signal processor is conducted to the at least one thermally conductive plate through the thermally conductive via hole.

### BRIEF DESCRIPTION OF THE DRAWINGS

To illustrate the technical solutions in the present disclosure more clearly, a brief introduction to the drawings that need to be used in some embodiments of the present disclosure will be provided below. Apparently, the drawings described below are merely the drawings in some embodiments of the present disclosure. Those of ordinary skill in the art can also derive other drawings from these drawings. Furthermore, the drawings described below can be regarded as schematic diagrams and are not intended to limit the actual dimensions of the products, the actual processes of the methods, or the actual timing of the signals involved in the embodiments of the present disclosure.

FIG. 1 is a connection relationship diagram of an optical communication system according to some embodiments of the present disclosure;

FIG. 2 is a partial structural diagram of a host computer according to some embodiments of the present disclosure;

FIG. 3 is a structural diagram of an optical module according to some embodiments of the present disclosure;

FIG. 4 is an exploded view of an optical module according to some embodiments of the present disclosure;

FIG. 5 is a schematic assembly diagram of a circuit board and a digital signal processor in an optical module according to some embodiments of the present disclosure;

FIG. 6 is a first schematic diagram of a partial structure of a circuit board in an optical module according to some embodiments of the present disclosure;

FIG. 7 is a second schematic diagram of a partial structure of a circuit board in an optical module according to some embodiments of the present disclosure;

FIG. 8 is a first partial assembly cross-sectional view of a circuit board and a digital signal processor in an optical module according to some embodiments of the present disclosure;

FIG. 9 is a second partial assembly cross-sectional view of a circuit board and a digital signal processor in an optical module according to some embodiments of the present disclosure;

FIG. 10 is a partial assembly diagram of a circuit board, a digital signal processor, and a lower shell part in an optical module according to some embodiments of the present disclosure;

FIG. 11 is an assembly cross-sectional view of a circuit board, a digital signal processor, and a lower shell part in an optical module according to some embodiments of the present disclosure;

FIG. 12 is a third partial assembly cross-sectional view of a circuit board and a digital signal processor in an optical module according to some embodiments of the present disclosure;

FIG. 13 is a fourth partial assembly cross-sectional view of a circuit board and a digital signal processor in an optical module according to some embodiments of the present disclosure;

FIG. 14 is a fifth partial assembly cross-sectional view of a circuit board and a digital signal processor in an optical module according to some embodiments of the present disclosure;

FIG. 15 is a schematic assembly diagram of an optical module and a cage of a host computer according to some embodiments of the present disclosure;

FIG. 16 is a schematic assembly diagram of a circuit board and an electrical connector in an optical module according to some embodiments of the present disclosure;

FIG. 17 is an assembly cross-sectional view of a circuit board and an electrical connector in an optical module according to some embodiments of the present disclosure; and

FIG. 18 is an assembly cross-sectional view, from another perspective, of a circuit board and an electrical connector in an optical module according to some embodiments of the present disclosure.

### DETAILED DESCRIPTION OF THE EMBODIMENTS

The technical solutions in some embodiments of the present disclosure will be clearly and detailedly described below with reference to the accompanying drawings. Apparently, the described embodiments are merely some rather than all of the embodiments of the present disclosure. All other embodiments obtained by those of ordinary skill in the art based on the embodiments provided in the present disclosure fall within the scope of protection of the present disclosure.

In optical communication technology, in order to establish information transmission between information processing devices, it is necessary to load information onto light and use the propagation of light to achieve the transmission of information. The light loaded with information is an optical signal. When the optical signal propagates in information transmission devices, the loss of optical power can be reduced, such that high-speed, long-distance, and low-cost information transmission can be achieved. The information that can be processed by the information processing devices exists in the form of electrical signals. Optical network units/gateways, routers, switches, mobile phones, computers, servers, tablet computers, and televisions are common information processing devices, while optical fibers and optical waveguides are common information transmission devices.

Optical modules enable the conversion between optical signals and electrical signals from the information processing devices and the information transmission devices. For example, an optical signal input or an optical signal output of an optical module is connected to an optical fiber, and an electrical signal input or an electrical signal output of the optical module is connected to an optical network unit; a first optical signal from the optical fiber is transmitted to the optical module, and the optical module converts the first optical signal into a first electrical signal and transmits the first electrical signal to the optical network unit; and a second electrical signal from the optical network unit is transmitted to the optical module, and the optical module converts the second electrical signal into a second optical signal and transmits the second optical signal to the optical fiber. Since the information processing devices can be interconnected via an electrical signal network, at least one type of information processing device needs to be directly connected to the optical module, and not all types of information processing devices need to be directly connected to the optical module. The information processing device directly connected to the optical module is referred to as a host computer of the optical module.

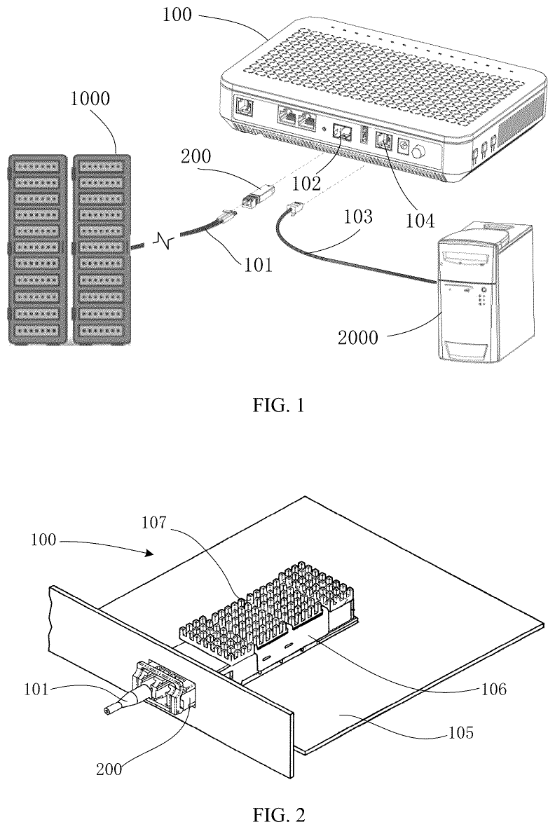

FIG. 1 is a connection relationship diagram of an optical communication system according to some embodiments of the present disclosure. As shown in FIG. 1, the optical communication system locally includes a remote information processing device 1000, a local information processing device 2000, a host computer 100, an optical module 200, an optical fiber 101, and a network cable 103.

One end of the optical fiber 101 extends toward the remote information processing device 1000, and the other end of the optical fiber 101 is connected to an optical interface of the optical module 200. An optical signal can undergo total reflection in the optical fiber 101. The propagation of the optical signal in the total reflection direction enables it to nearly maintain original optical power. The optical signal undergoes multiple total reflections in the optical fiber 101 to transmit an optical signal from the remote information processing device 1000 to the optical module 200 or to propagate light from the optical module 200 to the remote information processing device 1000, thereby achieving long-distance and low-power-loss information transmission.

The number of optical fibers 101 may be one or more (two or more). The optical fiber 101 and the optical module 200 may be movably connected in a pluggable manner or fixedly connected.

The host computer 100 is provided with an optical module interface 102. The optical module interface 102 is configured to be connected to the optical module 200, thereby establishing a unidirectional/bidirectional electrical signal connection between the host computer 100 and the optical module 200. The host computer 100 is configured to provide a data signal to the optical module 200, receive a data signal from the optical module 200, or monitor and control a working state of the optical module 200.

The host computer 100 is provided with an external electrical interface, such as a universal serial bus (USB) interface or a network cable interface 104. The external electrical interface can be connected to the electrical signal network. For example, the network cable interface 104 is configured to be connected to the network cable 103, thereby establishing a unidirectional/bidirectional electrical signal connection between the host computer 100 and the network cable 103.

Optical network units (ONUs), optical line terminals (OLTs), optical network terminals (ONTs), and data center servers are common host computers.

One end of the network cable 103 is connected to the local information processing device 2000, and the other end of the network cable 103 is connected to the host computer 100, thereby establishing an electrical signal connection between the local information processing device 2000 and the host computer 100 via the network cable 103.

For example, a third electrical signal sent by the local information processing device 2000 is transmitted to the host computer 100 via the network cable 103. The host computer 100 generates a second electrical signal based on the third electrical signal. The second electrical signal from the host computer 100 is transmitted to the optical module 200. The optical module 200 converts the second electrical signal into a second optical signal and transmits the second optical signal to the optical fiber 101. The second optical signal is transmitted through the optical fiber 101 to the remote information processing device 1000.

For example, a first optical signal from the remote information processing device 1000 is propagated through the optical fiber 101. The first optical signal from the optical fiber 101 is transmitted to the optical module 200. The optical module 200 converts the first optical signal into a first electrical signal and transmits the first electrical signal to the host computer 100. The host computer 100 generates a fourth electrical signal based on the first electrical signal and transmits the fourth electrical signal to the local information processing device 2000.

The optical module is a tool to implement the conversion between optical signals and electrical signals. During the conversion between the optical signals and the electrical signals, the information remains unchanged, and the encoding and decoding methods for the information may vary.

FIG. 2 is a partial structural diagram of a host computer according to some embodiments of the present disclosure. To clearly show the connection relationship between the optical module 200 and the host computer 100, FIG. 2 shows only the structure of the host computer 100 related to the optical module 200. As shown in FIG. 2, the host computer 100 further includes a PCB 105 disposed in a housing, a cage 106 disposed on the surface of the PCB 105, a heat sink 107 disposed on the cage 106, and an electrical connector disposed inside the cage 106 (not shown in the figure). The heat sink 107 has a protruding structure to increase the heat dissipation area. A fin-shaped structure is a common protruding structure.

The optical module 200 is inserted into the cage 106 of the host computer 100, and the optical module 200 is fixed by the cage 106. Heat generated by the optical module 200 is conducted to the cage 106 and then diffused through the heat sink 107. After the optical module 200 is inserted into the cage 106, the electrical interface of the optical module 200 is connected to the electrical connector inside the cage 106.

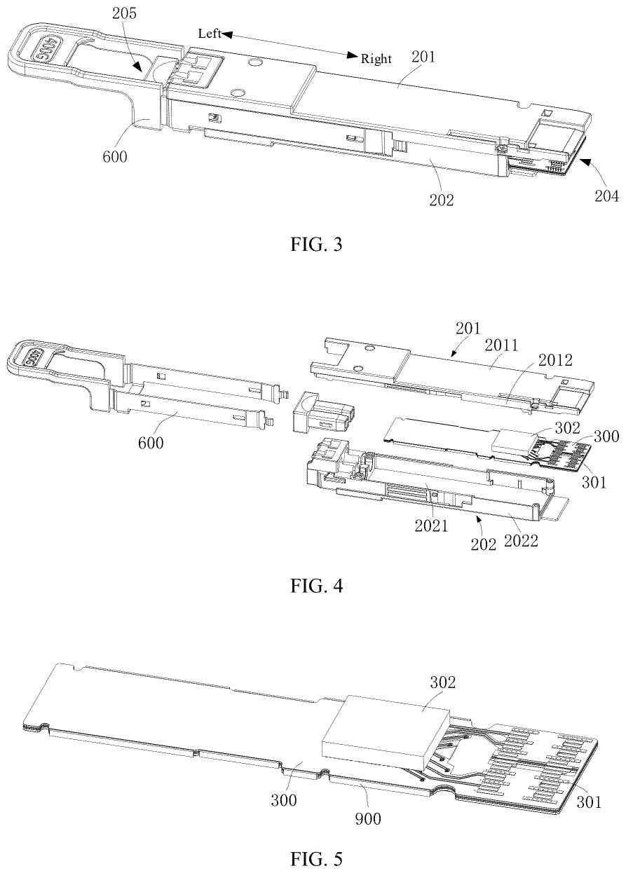

FIG. 3 is a structural diagram of an optical module according to some embodiments of the present disclosure. FIG. 4 is an exploded view of an optical module according to some embodiments of the present disclosure. As shown in FIG. 3 and FIG. 4, the optical module 200 includes a shell, a circuit board 300 disposed in the shell, and optoelectronic devices, an optical emission component, and an optical reception component which are disposed on the circuit board 300. However, the present disclosure is not limited to this. In some embodiments, the optical module 200 includes either an optical emission component or an optical reception component.

The shell includes an upper shell part 201 and a lower shell part 202, where the upper shell part 201 covers the lower shell part 202 to form the shell with an opening 204 and an opening 205; and the outer contour of the shell is generally square.

In some embodiments, the lower shell part 202 includes a bottom plate 2021 and two lower side plates 2022 located at two sides of the bottom plate 2021 and perpendicular to the bottom plate 2021; and the upper shell part 201 includes a cover plate 2011, where the cover plate 2011 covers the two lower side plates 2022 of the lower shell part 202 to form the shell.

In some embodiments, the lower shell part 202 includes a bottom plate 2021 and two lower side plates 2022 located at two sides of the base plate 2021 and perpendicular to the bottom plate 2021; and the upper shell 201 includes a cover plate 2011 and two upper side plates 2012 located at two sides of the cover plate 2011 and perpendicular to the cover plate 2011, where the two upper side plates 2012 and the two lower side plates 2022 are combined to ensure that the upper shell part 201 covers the lower shell part 202.

The direction of a connecting line between the opening 204 and the opening 205 may be consistent with the length direction of the optical module 200 or may be inconsistent with the length direction of the optical module 200. For example, the opening 204 is located at the end of the optical module 200 (the right end of FIG. 3), and the opening 205 is also located at the end of the optical module 200 (the left end of FIG. 3). Alternatively, the opening 204 is located at the end of the optical module 200, and the opening 205 is located at the side of the optical module 200. The opening 204 is an electrical interface, and gold fingers 301 of the circuit board 300 extend out from the electrical interface and are inserted into the electrical connector of the host computer; and the opening 205 is an optical port, which is configured to be connected to the optical fiber 101 such that the optical fiber 101 is connected to the optical emission component and/or the optical reception component in the optical module 200.

The assembly method of combining the upper shell part 201 with the lower shell part 202 is adopted, such that the circuit board 300, the optoelectronic devices, the optical emission component and/or the optical reception component, and other components can be conveniently mounted in the shell, and these components can be packaged by the upper shell part 201 and the lower shell part 202 for protection. In addition, when the circuit board 300, the optoelectronic devices, the optical emission component and/or the optical reception component, and other components are assembled, it is convenient for the deployment of positioning parts, heat dissipation parts, and electromagnetic shielding parts of these components, and is conducive to the automatic production.

In some embodiments, the upper shell part 201 and the lower shell part 202 are made of metal materials, which is conducive to electromagnetic shielding and heat dissipation.

In some embodiments, the optical module 200 further includes an unlocking component 600 located outside its shell. The unlocking component 600 is configured to achieve a fixed connection between the optical module 200 and the host computer, or to release the fixed connection between the optical module 200 and the host computer.

For example, the unlocking component 600 is located outside the two lower side plates 2022 of the lower shell part 202, and includes a clamping component that matches the cage 106 of the host computer. When the optical module 200 is inserted into the cage 106, the optical module 200 is fixed in the cage 106 by the clamping component of the unlocking component 600; and when the unlocking component 600 is pulled, the clamping component of the unlocking component 600 moves accordingly, such that the connection relationship between the clamping component and the host computer is changed to release the fixation of the optical module 200 to the host computer, thereby pulling out the optical module 200 from the cage 106.

The circuit board 300 includes circuit traces, electronic components, and chips, where the electronic components and the chips are connected together through the circuit traces according to the circuit design to implement the functions such as power supply, electrical signal transmission, and grounding. The electronic components may include, for example, capacitors, resistors, transistors, and metal-oxide-semiconductor field-effect transistors (MOSFETs). The chips may include, for example, microcontroller units (MCUs), laser driving chips, transimpedance amplifiers (TIAs), limiting amplifiers (LAs), clock and data recovery (CDR) chips, power management chips, and digital signal processing (DSP) chips.

The circuit board 300 is generally a rigid circuit board. The rigid circuit board can also achieve the bearing effect because of its relatively hard material, for example, the rigid circuit board can smoothly carry the above-mentioned electronic components and chips. The rigid circuit board can also be conveniently inserted into the electrical connector in the cage of the host computer.

The circuit board 300 further includes gold fingers 301 formed on the end surface thereof, where each gold finger 301 includes a plurality of independent pins. The circuit board 300 is inserted into the cage 106, and the gold fingers 301 are connected to the electrical connector in the cage 106. The gold fingers 301 may be disposed only on the surface of one side of the circuit board 300 (such as the upper surface shown in FIG. 4), or may be disposed on the surfaces of the upper and lower sides of the circuit board 300 to provide more pins. The gold fingers 301 are configured to establish an electrical connection with the host computer to achieve power supply, grounding, inter-integrated circuit (I2C) signal transmission, data signal transmission, etc.

Certainly, flexible circuit boards may also be used in some optical modules. The flexible circuit boards are generally used in conjunction with rigid circuit boards as a supplement to the rigid circuit boards.

FIG. 5 is a schematic assembly diagram of a circuit board and a digital signal processor in an optical module according to some embodiments of the present disclosure. As shown in FIG. 5, the DSP chip 302 on the circuit board 300 is electrically connected to the circuit board 300 and is electrically connected to the gold fingers 301 on the circuit board 300 via signal traces, such that the electrical signal received by the gold fingers 301 is transmitted to the DSP chip 302, and then the DSP chip 302 transmits the electrical signal via the signal traces to the optical emission component of the optical module 200, so as to achieve optical emission.

After the optical reception component of the optical module converts the external optical signal into an electrical signal, the electrical signal is processed by the DSP chip 302, then transmitted to the gold fingers 301, and further transmitted via the gold fingers 301 to the host computer 100, so as to achieve optical reception.

In some embodiments, the DSP chip 302 is electrically connected to the gold fingers 301 on the circuit board 300 via a power wiring, so as to supply power to the DSP chip 302.

In some embodiments, the voltage provided by the gold fingers 301 is generally 3.3 V. If the power supply voltage required by the DSP chip 302 is less than 3.3 V, a power chip is disposed on the circuit board 300, where one end of the power chip is electrically connected to the gold fingers 301 via a power wiring, and the other end of the power chip is electrically connected to the DSP chip 302 via a power wiring. The voltage provided by the gold fingers 301 is processed by the power chip, and the processed voltage is then transmitted to the DSP chip 302.

Since the DSP chip 302 receives the electrical signal provided by the gold fingers 301, the electrical signal is processed by the DSP chip 302 and then transmitted to the optical emission component, and the electrical signal output by the optical reception component is processed by the DSP chip 302 and then transmitted to the gold fingers 301, the DSP chip 302 is an electronic chip with the highest power consumption in the optical module and generates relatively high heat during operation.

To dissipate the heat from the DSP chip 302, the DSP chip 302 can contact the upper shell part 201, or the DSP chip 302 can contact the lower shell part 202 via the circuit board 300, so as to transfer the heat generated during operation of the DSP chip 302 to the shell of the optical module. However, the contact area between the DSP chip 302 and the upper shell part 201 or the circuit board 300 is relatively small, resulting in low heat dissipation efficiency for the DSP chip.

To solve the above problem, the present disclosure provides an optical module, where the heat from the DSP chip is transferred to a side wall of the lower shell part via a thermally conductive layer on the surface of the circuit board, then transferred to a thermally conductive plate in an inner layer of the circuit board through a thermally conductive via hole in the circuit board, and further transferred to the side wall of the lower shell part via the thermally conductive plate, such that heat dissipation channels are added, thereby improving heat dissipation efficiency.

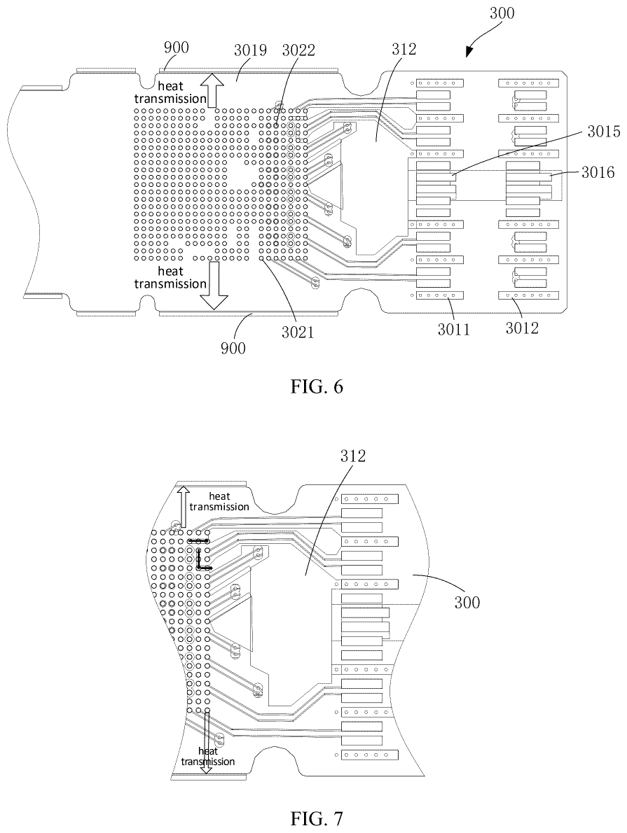

FIG. 6 is a first schematic diagram of a partial structure of a circuit board in an optical module according to some embodiments of the present disclosure. As shown in FIG. 6, the DSP chip 302 is provided with many interfaces connected to the outside, and thus is connected to the circuit board 300 and the optical emission component and/or the optical reception component via these interfaces. When the DSP chip 302 is connected to the circuit board 300, it is mainly mounted on the circuit board 300 via BGA solder balls to achieve electrical communication.

In some embodiments, when the DSP chip 302 is mounted on the circuit board 300 via BGA solder balls, electrical interfaces of the BGA solder balls are in the form of a rectangular array, i.e., the BGA solder balls are evenly arranged on the bottom surface of the DSP chip 302, and then the BGA solder balls are attached to the surface of the circuit board 300, so as to achieve an electrical connection between the DSP chip 302 and the circuit board 300 via the BGA solder balls.

In some embodiments, the circuit board 300 includes multiple layer boards. To improve heat dissipation efficiency of the DSP chip 302, a thermally conductive layer 3019 can be plated on an upper surface of the circuit board 300, an edge of the thermally conductive layer 3019 can contact the lower side plates 2022 of the lower shell part 202, and the thermally conductive layer 3019 can be directly connected to ground solder balls in the BGA solder balls. In this way, the heat from the DSP chip 302 is transferred to the thermally conductive layer 3019 via the ground solder balls, and then directly transferred to the lower side plates 2022 of the lower shell part 202 via the thermally conductive layer 3019.

In some embodiments, ground solder balls at an edge of the DSP chip 302 can directly reach an edge of the circuit board 300 via the thermally conductive layer 3019 on the surface of the circuit board 300, thereby directly transferring part of the heat from the DSP chip 302 to the lower shell part 202.

FIG. 7 is a second schematic diagram of a partial structure of a circuit board in an optical module according to some embodiments of the present disclosure. As shown in FIG. 7, since the ground solder balls at the edge of the DSP chip 302 are connected to the thermally conductive layer 3019 on the surface of the circuit board 300 to directly transfer part of the heat from the DSP chip 302 to the lower shell part 202, ground solder balls at an inner side of the DSP chip can be connected to the ground solder balls at the edge of the DSP chip 302, thereby adding heat dissipation channels from the DSP chip 302 to the thermally conductive layer 3019.

In some embodiments, a thermally conductive connecting block 312 is disposed on the upper surface of the circuit board 300, and the thermally conductive connecting block 312 can directly extend from the ground solder balls at the edge of the DSP chip 302 to the ground solder balls at the inner side of the DSP chip 302. The heat transferred by the ground solder balls at the inner side of the DSP chip 302 is transferred to the ground solder balls at the edge of the DSP chip 302 via the thermally conductive connecting block 312, and then the heat is transferred to the thermally conductive layer 3019 on the surface of the circuit board 300 via the ground solder balls at the edge of the DSP chip 302, such that the heat is transferred to the lower shell part 202 via the thermally conductive layer 3019.

In some embodiments, the thermally conductive connecting block 312 can connect ground solder balls close to the edge of the DSP chip 302 to the ground solder balls at the edge of the DSP chip 302. Since the BGA solder balls of the DSP chip 302 also include signal solder balls and power solder balls, if the thermally conductive connecting block 312 is connected to the signal solder balls or the power solder balls, electrical signal transmission of the DSP chip 302 may be affected. Therefore, the thermally conductive connecting block 312 cannot extend to the entire solder ball region of the DSP chip 302.

To improve heat dissipation efficiency of the DSP chip 302, the circuit board 300 can be provided with a via hole. The heat from the DSP chip 302 is transferred to the inner layer of the circuit board 300 through the via hole, and further transferred to the lower side plates 2022 of the lower shell part 202 via the inner layer of the circuit board 300.

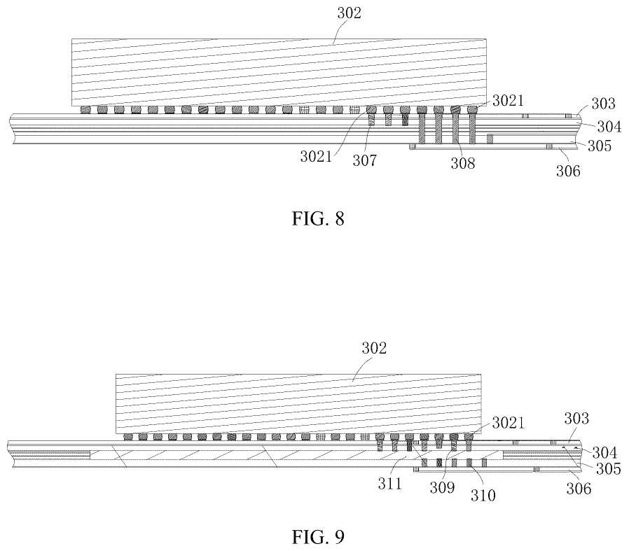

FIG. 8 is a first partial assembly cross-sectional view of a circuit board and a digital signal processor in an optical module according to some embodiments of the present disclosure. As shown in FIG. 8, the circuit board 300 includes an upper layer board 303, a lower layer board 306, and a thermally conductive plate, where the upper layer board 303, the thermally conductive plate, and the lower layer board 306 are arranged in a stacked manner, the thermally conductive layer 3019 is plated on the upper layer board 303, and a side of the thermally conductive plate contacts the corresponding lower side plate 2022 of the lower shell part 202.

A thermally conductive via hole can be provided between the upper layer board 303 and the thermally conductive plate, and two ends of the thermally conductive via hole are respectively connected to the ground solder balls of the DSP chip 302 and the thermally conductive plate in the inner layer of the circuit board 300. In this way, the heat from the DSP chip 302 can be transferred to the thermally conductive plate in the inner layer of the circuit board 300 through the thermally conductive via hole, and then transferred to the lower side plates 2022 of the lower shell part 202 via the thermally conductive plate.

In some embodiments, in order to transfer the heat from the DSP chip 302 via the thermally conductive plate in the inner layer of the circuit board 300, the number of layers of the thermally conductive plate inside the circuit board 300 is greater than or equal to one, and an area of at least one thermally conductive plate is larger than an area of the DSP chip 302, so as to improve heat dissipation efficiency of the thermally conductive plate.

In some embodiments, the circuit board 300 includes a first thermally conductive plate 304 and a second thermally conductive plate 305, where the first thermally conductive plate 304 is located between the upper layer board 303 and the lower layer board 306, and the second thermally conductive plate 305 is located between the first thermally conductive plate 304 and the lower layer board 306, such that the upper layer board 303, the first thermally conductive plate 304, the second thermally conductive plate 305, and the lower layer board 306 are arranged in a stacked manner.

Opposite sides of the first thermally conductive plate 304 may contact the lower side plates 2022 of the lower shell part 202, and opposite sides of the second thermally conductive plate 305 may not contact the lower side plates 2022 of the lower shell part 202, such that heat is transferred to the lower shell part 202 via the first thermally conductive plate 304; or, the opposite sides of the first thermally conductive plate 304 may not contact the lower side plates 2022 of the lower shell part 202, and the opposite sides of the second thermally conductive plate 305 may contact the lower side plates 2022 of the lower shell part 202, such that heat is transferred to the lower shell part 202 via the second thermally conductive plate 305; or, the opposite sides of the first thermally conductive plate 304 and the opposite sides of the second thermally conductive plate 305 may both contact the lower side plates 2022 of the lower shell part 202, such that heat is transferred to the lower shell part 202 via the first thermally conductive plate 304 and the second thermally conductive plate 305.

A first thermally conductive via hole 307 is provided between the upper layer board 303 and the first thermally conductive plate 304, where one end of the first thermally conductive via hole 307 is connected to the ground solder balls of the DSP chip 302, and the other end of the first thermally conductive via hole 307 is connected to the first thermally conductive plate 304, such that part of the heat from the DSP chip 302 is conducted to the first thermally conductive plate 304 through the first thermally conductive via hole 307.

When a side of the first thermally conductive plate 304 contacts the corresponding lower side plate 2022, the first thermally conductive plate 304 directly transfers heat to the lower shell part 202. When the first thermally conductive plate 304 does not contact the lower side plates 2022 and the second thermally conductive plate 305 contacts the lower side plates 2022, since a dielectric is arranged between the first thermally conductive plate 304 and the second thermally conductive plate 305, the first thermally conductive plate 304 can transfer heat to the second thermally conductive plate 305 via the dielectric, and then the second thermally conductive plate 305 transfers the heat to the lower shell part 202.

In some embodiments, a second thermally conductive via hole 308 is provided between the upper layer board 303 and the second thermally conductive plate 305, where one end of the second thermally conductive via hole 308 is connected to the ground solder balls of the DSP chip 302, and the other end of the second thermally conductive via hole 308 is connected to the second thermally conductive plate 305, such that part of the heat from the DSP chip 302 is transferred to the second thermally conductive plate 305 through the second thermally conductive via hole 308.

When the side of the first thermally conductive plate 304 contacts the corresponding lower side plate 2022 and a side of the second thermally conductive plate 305 does not contact the corresponding lower side plate 2022, the second thermally conductive plate 305 transfers heat to the first thermally conductive plate 304 via the dielectric, and then the first thermally conductive plate 304 transfers the heat to the lower shell part 202. When the side of the second thermally conductive plate 305 contacts the corresponding lower side plate 2022, the second thermally conductive plate 305 directly transfers heat to the lower shell part 202.

In some embodiments, the first thermally conductive plate 304 and the second thermally conductive plate 305 are thermally conductive copper plates. There may be copper planes with other attributes in the circuit board 300. Except for the copper planes with specified heat dissipation attributes (the thermally conductive copper plates) that can be plated with copper on edge sides and connected to the lower shell part 202, the copper planes with other attributes do not extend to an edge side of the circuit board 300 and are not connected to the copper planes with specified heat dissipation attributes, so as to avoid affecting signal transmission between the circuit board 300 and the DSP chip 302.

In some embodiments, since different electrical signals exist on the DSP chip 302, and the signal traces may need to pass through different layers of the circuit board 300 when the different electrical signals are transmitted on the circuit board 300, the thermally conductive plate in the circuit board 300 needs to avoid via holes with different attributes in order to prevent interference with the transmission of the different electrical signals to the DSP chip 302, i.e., holes need to be provided in the thermally conductive plate to allow the via holes to pass through.

FIG. 9 is a second partial assembly cross-sectional view of a circuit board and a digital signal processor in an optical module according to some embodiments of the present disclosure. As shown in FIG. 9, when the DSP chip 302 is connected to the thermally conductive plate inside the circuit board 300 through the thermally conductive via hole, a thermally conductive block 311 can be embedded in the inner layer of the circuit board 300 to transfer heat more efficiently to the thermally conductive plate, where the thermally conductive block 311 is disposed between the upper layer board 303 and the second thermally conductive plate 305. In some embodiments, the thermally conductive block 311 may be a thermally conductive copper block.

By way of example, a mounting hole is provided between the upper layer board 303 and the second thermally conductive plate 305, the thermally conductive block 311 is embedded in the mounting hole, and a side of the thermally conductive block 311 contacts the first thermally conductive plate 304 and the second thermally conductive plate 305. An area of the thermally conductive block 311 can be greater than the area of the DSP chip 302, and a third thermally conductive via hole 309 is provided between the upper layer board 303 and the thermally conductive block 311, where one end of the third thermally conductive via hole 309 is connected to the ground solder balls of the DSP chip 302, and the other end of the third thermally conductive via hole 309 is connected to the thermally conductive block 311, such that the heat from the DSP chip 302 is quickly transferred to the first thermally conductive plate 304 and the second thermally conductive plate 305 through the thermally conductive block 311, thereby improving heat dissipation efficiency.

In some embodiments, a bottom surface of the thermally conductive block 311 can contact a bottom surface of the second thermally conductive plate 305. The heat from the DSP chip 302 is transferred to the thermally conductive block 311 through the third thermally conductive via hole 309, and the thermally conductive block 311 then transfers the heat to the first thermally conductive plate 304 and the second thermally conductive plate 305 respectively, such that the heat is transferred to the lower shell part 202 through the first thermally conductive plate 304 and the second thermally conductive plate 305, thereby improving heat dissipation efficiency.

In some embodiments, the bottom surface of the thermally conductive block 311 can also contact a top surface of the second thermally conductive plate 305. A fourth thermally conductive via hole 310 can be provided between the bottom surface of the thermally conductive block 311 and the bottom surface of the second thermally conductive plate 305, such that the heat from the thermally conductive block 311 is transferred to the second thermally conductive plate 305 through the fourth thermally conductive via hole 310, thereby improving heat dissipation efficiency.

In some embodiments, since the BGA solder balls of the DSP chip 302 also include solder balls with other attributes such as signal solder balls and power solder balls, and the thermally conductive block 311 is only provided to improve heat dissipation efficiency, the via holes connected to the solder balls with other attributes, except for the ground solder balls, are not connected to the thermally conductive block 311 when electrically connected through the solder balls on the circuit board 300, so as to avoid affecting the performance of the solder balls with other attributes.

In some embodiments, when the ground solder balls of the DSP chip 302 are connected to the thermally conductive plate and the thermally conductive block 311 in the inner layer of the circuit board 300 through the thermally conductive via holes, heat is transferred to a side of the circuit board 300 via the thermally conductive plate. In order to transfer the heat to the lower shell part 202, the side of the circuit board 300 can directly or indirectly contact the corresponding lower side plate 2022 of the lower shell part 202.

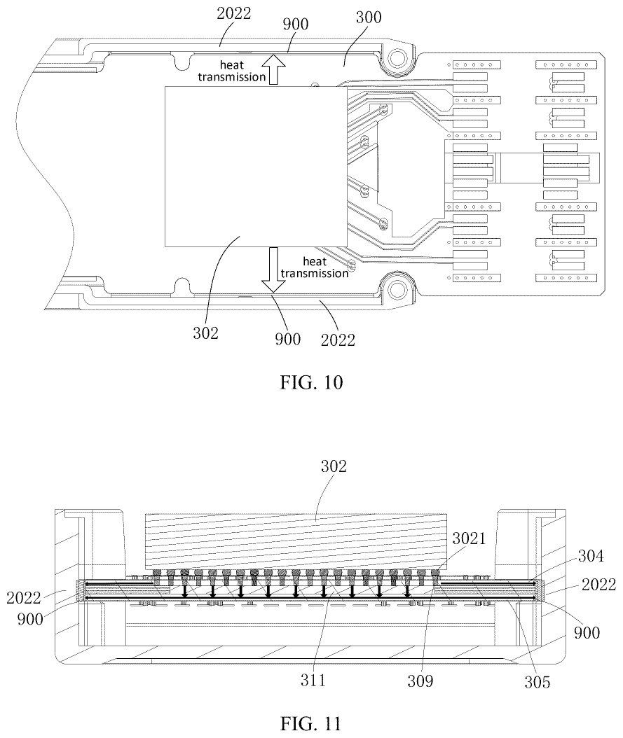

FIG. 10 is a partial assembly diagram of a circuit board, a digital signal processor, and a lower shell part in an optical module according to some embodiments of the present disclosure. FIG. 11 is an assembly cross-sectional view of a circuit board, a digital signal processor, and a lower shell part in an optical module according to some embodiments of the present disclosure. As shown in FIG. 10 and FIG. 11, when the side of the circuit board 300 directly contacts the corresponding lower side plate 2022 of the lower shell part 202, the two opposite sides of the circuit board 300 are plated with metal layers. The metal layers directly contact the lower side plates 2022, so as to improve heat dissipation efficiency between the circuit board 300 and the lower shell part 202.

In some embodiments, when the sides of the circuit board 300 are plated with metal layers, in order to avoid the risk of electrostatic discharge (ESD), gaps exist between the metal layers and the thermally conductive plate in the circuit board 300, so as to prevent the metal layers from directly contacting the thermally conductive plate. The thermally conductive plate in the inner layer of the circuit board 300 conducts heat to the metal layers at the sides of the circuit board 300 by means of thermal conduction, and then the heat is transferred to the lower shell part 202 through the metal layers.

In some embodiments, the two opposite sides of the circuit board 300 can be provided with thermally conductive pads 900. The thermally conductive pads 900 are in contact with the lower side plates 2022 of the lower shell part 202, so as to achieve indirect contact between the metal layers at the sides of the circuit board 300 and the lower side plates 2022 through the thermally conductive pads 900. The thermally conductive pads 900 are high-performance ones, which conduct heat only and are electrically insulating, so as to prevent ESD.

In some embodiments, when the circuit board 300 contacts the lower side plates 2022 of the lower shell part 202 through the thermally conductive pads 900, a thickness of each thermally conductive pad 900 is 2 to 10 mm in order to improve heat dissipation efficiency.

In some embodiments, the gold fingers 301 disposed at the end of the circuit board 300 include high-speed signal gold fingers, low-speed signal gold fingers, power gold fingers, and ground gold fingers, where the ground gold fingers account for the largest proportion, followed by the power gold fingers, and an area of each power gold finger is relatively large. When the DSP chip 302 is connected to the power gold fingers via a power wiring, the power wiring can also conduct heat. Therefore, when the heat from the DSP chip 302 is transferred to the lower shell part 202 through the thermally conductive plate in the inner layer of the circuit board 300, the power gold fingers can also dissipate the heat from the DSP chip 302.

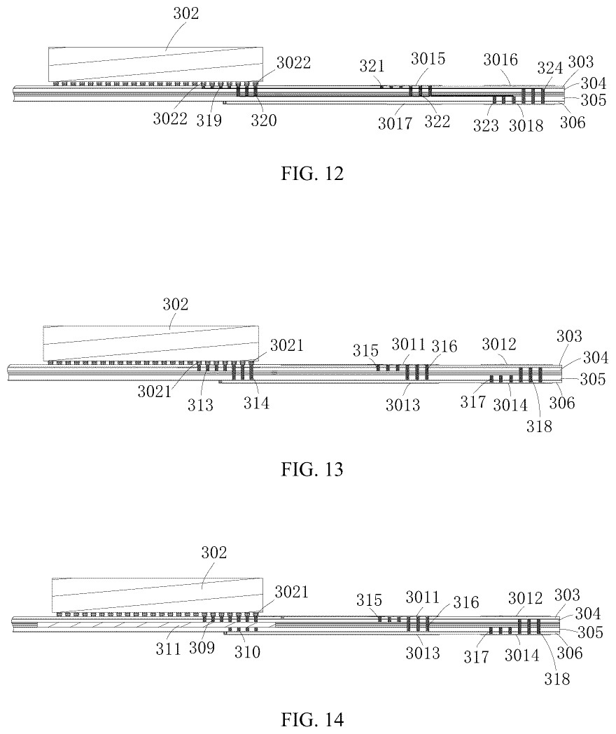

FIG. 12 is a third partial assembly cross-sectional view of a circuit board and a digital signal processor in an optical module according to some embodiments of the present disclosure. As shown in FIG. 12, the thermally conductive plate in the inner layer of the circuit board 300 is provided thereon with a clearance groove, where the clearance groove accommodates a power wiring; and a via hole is provided between the upper layer board 303 and the thermally conductive plate in the inner layer of the circuit board 300, where one end of the via hole is electrically connected to the power solder balls 3022 of the DSP chip 302, and the other end of the via hole is electrically connected to the power wiring.

When the thermally conductive plate in the inner layer of the circuit board 300 includes a first thermally conductive plate 304 and a second thermally conductive plate 305, a power wiring can be arranged on each of the first thermally conductive plate 304 and the second thermally conductive plate 305. The DSP chip 302 is electrically connected to the power wirings on the first thermally conductive plate 304 and the second thermally conductive plate 305 via different via holes.

One end of the circuit board 300 is provided with power gold fingers. A via hole is provided between the power gold fingers and the thermally conductive plate in the inner layer of the circuit board 300, where one end of the via hole is electrically connected to the power gold fingers, and the other end of the via hole is electrically connected to the power wiring, thereby achieving an electrical connection between the power solder balls 3022 of the DSP chip 302 and the power gold fingers on the circuit board 300.

The power solder balls 3022 of the DSP chip 302 and the power gold fingers on the circuit board 300 achieve both electrical signal conduction and heat transfer, thereby achieving the electrical and thermal multiplexing effect.

In some embodiments, a first via hole 319 is provided between the upper layer board 303 and the first thermally conductive plate 304, where one end of the first via hole 319 is electrically connected to the power solder balls 3022 of the DSP chip 302, and the other end of the first via hole 319 is electrically connected to the power wiring on the first thermally conductive plate 304; and a second via hole 320 is provided between the upper layer board 303 and the second thermally conductive plate 305, where one end of the second via hole 320 is electrically connected to the power solder balls 3022 of the DSP chip 302, and the other end of the second via hole 320 is electrically connected to the power wiring on the second thermally conductive plate 305.

To improve heat dissipation efficiency, the power gold fingers on the upper layer board 303 of the circuit board 300 include a first row of power gold fingers 3015 and a second row of power gold fingers 3016, where the second row of power gold fingers 3016 is located at an edge of the upper layer board 303, and the first row of power gold fingers 3015 is located between the second row of power gold fingers 3016 and the DSP chip 302.

A third via hole is provided between the first row of power gold fingers 3015 and the thermally conductive plate, where one end of the third via hole is electrically connected to the first row of power gold fingers 3015, and the other end of the third via hole is electrically connected to the power wiring on the thermally conductive plate; and a fourth via hole is provided between the second row of power gold fingers 3016 and the thermally conductive plate, where one end of the fourth via hole is electrically connected to the second row of power gold fingers 3016, and the other end of the fourth via hole is electrically connected to the power wiring on the thermally conductive plate.

When the inner layer of the circuit board 300 includes a first thermally conductive plate 304 and a second thermally conductive plate 305, the third via hole includes a first sub-via hole 321 and a second sub-via hole 322, where two ends of the first sub-via hole 321 are respectively connected to the first row of power gold fingers 3015 and the first thermally conductive plate 304, and two ends of the second sub-via hole 322 are respectively connected to the first row of power gold fingers 3015 and the second thermally conductive plate 305, thereby transferring the heat from the first thermally conductive plate 304 and the second thermally conductive plate 305 to the first row of power gold fingers 3015 respectively.

Two ends of one sub-via hole of the fourth via hole are respectively connected to the second row of power gold fingers 3016 and the first thermally conductive plate 304, and two ends of another sub-via hole of the fourth via hole are respectively connected to the second row of power gold fingers 3016 and the second thermally conductive plate 305, thereby transferring the heat from the first thermally conductive plate 304 and the second thermally conductive plate 305 to the second row of power gold fingers 3016 respectively.

The power solder balls 3022 of the DSP chip 302 are electrically connected to the power wiring on the thermally conductive plate through the via hole, the power wiring is electrically connected to the first row of power gold fingers 3015 through the third via hole and is electrically connected to the second row of power gold fingers 3016 through the fourth via hole, and the heat from the DSP chip 302 is transferred to the power gold fingers on the upper layer board 303 through the via hole and the power wiring, thereby achieving the electrical and thermal multiplexing effect.

In some embodiments, in order to improve heat dissipation efficiency, the power gold fingers can also be disposed on the lower layer board 306 of the circuit board 300, that is, a third row of power gold fingers 3017 and a fourth row of power gold fingers 3018 are disposed at one end of the lower layer board 306, where the fourth row of power gold fingers 3018 is located at the end of the lower layer board 306, and the third row of power gold fingers 3017 is located between the DSP chip 302 and the fourth row of power gold fingers 3018.

A fifth via hole is provided between the third row of power gold fingers 3017 and the thermally conductive plate in the inner layer of the circuit board 300, where the third row of power gold fingers 3017 is electrically connected to the power wiring on the thermally conductive plate through the fifth via hole; and a sixth via hole is provided between the fourth row of power gold fingers 3018 and the thermally conductive plate in the inner layer of the circuit board 300, where the fourth row of power gold fingers 3018 is electrically connected to the power wiring on the thermally conductive plate through the sixth via hole, such that the power solder balls 3022 on the DSP chip 302 are electrically connected to the power gold fingers on the lower layer board 306 of the circuit board 300, and heat is transferred during electrical signal transmission, thereby achieving the electrical and thermal multiplexing effect.

When the thermally conductive plate in the inner layer of the circuit board 300 includes a first thermally conductive plate 304 and a second thermally conductive plate 305, two ends of one sub-via hole of the fifth via hole are respectively connected to the third row of power gold fingers 3017 and the second thermally conductive plate 305, and two ends of another sub-via hole of the fifth via hole are respectively connected to the third row of power gold fingers 3017 and the first thermally conductive plate 304, thereby transferring the heat from the first thermally conductive plate 304 and the second thermally conductive plate 305 to the third row of power gold fingers 3017 respectively.

The sixth via hole includes a third sub-via hole 323 and a fourth sub-via hole 324, where two ends of the third sub-via hole 323 are respectively connected to the fourth row of power gold fingers 3018 and the second thermally conductive plate 305, and two ends of the fourth sub-via hole 324 are respectively connected to the fourth row of power gold fingers 3018 and the first thermally conductive plate 304, thereby transferring the heat from the first thermally conductive plate 304 and the second thermally conductive plate 305 to the fourth row of power gold fingers 3018 respectively.

The power solder balls 3022 of the DSP chip 302 are electrically connected to the power wiring on the thermally conductive plate through the via hole, the power wiring is electrically connected to the third row of power gold fingers 3017 via the fifth via hole and is electrically connected to the fourth row of power gold fingers 3018 via the sixth via hole, and the heat from the DSP chip 302 is transferred to the power gold fingers on the lower layer board 306 through the via hole and the power wiring, thereby achieving the electrical and thermal multiplexing effect.

In the optical module provided by the present disclosure, there are two heat dissipation paths for the heat from the DSP chip 302. One is that the ground solder balls of the DSP chip 302 are connected to the thermally conductive plate in the inner layer of the circuit board 300 through the thermally conductive via hole, and the edge side of the thermally conductive plate is in direct or indirect contact with the corresponding lower side plate of the lower shell part 202, such that the heat from the DSP chip 302 is transferred to the lower shell part 202 through the thermally conductive plate in the inner layer of the circuit board 300, while the solder balls with other attributes of the DSP chip 302 provide auxiliary heat dissipation. The other is that the power solder balls of the DSP chip 302 are electrically connected to the power wiring on the thermally conductive plate in the inner layer of the circuit board 300 through the thermally conductive via hole, and the power wiring is electrically connected to a power pad on the upper layer board 303 and/or the lower layer board 306 of the circuit board 300 through the thermally conductive via hole, such that the heat is transferred during electrical signal transmission, thereby achieving the electrical and thermal multiplexing effect, while the solder balls with other attributes of the DSP chip 302 provide auxiliary heat dissipation.

Both of the two heat dissipation methods above can achieve heat dissipation to the side wall of the optical module in the same or different layers of the circuit board 300, thereby improving heat dissipation efficiency.

In some embodiments, among the gold fingers 301 disposed at the end of the circuit board 300, the ground gold fingers account for the largest proportion. When the DSP chip 302 and the power gold fingers on the circuit board 300 undergo electrical and thermal multiplexing, the thermally conductive plate in the inner layer of the circuit board 300 can also be connected to the ground gold fingers on the surface of the circuit board 300, such that heat is dissipated through the ground gold fingers, thereby further improving heat dissipation efficiency.

FIG. 13 is a fourth partial assembly cross-sectional view of a circuit board and a digital signal processor in an optical module according to some embodiments of the present disclosure. As shown in FIG. 13, a fifth thermally conductive via hole is provided between the upper layer board 303 and the thermally conductive plate, where two ends of the fifth thermally conductive via hole are respectively connected to the ground solder balls of the DSP chip 302 and the thermally conductive plate in the inner layer of the circuit board 300, such that the heat from the DSP chip 302 can be transferred to the thermally conductive plate in the inner layer of the circuit board 300 through the fifth thermally conductive via hole.

A sixth thermally conductive via hole is provided between the ground gold fingers of the circuit board 300 and the thermally conductive plate, where two ends of the sixth thermally conductive via hole are respectively connected to the ground gold fingers and the thermally conductive plate, such that the heat from the thermally conductive plate can be transferred to the ground gold fingers on the surface of the circuit board 300 through the sixth thermally conductive via hole.

In some embodiments, in order to transfer the heat from the DSP chip 302 via the thermally conductive plate in the inner layer of the circuit board 300, the number of layers of the thermally conductive plate inside the circuit board 300 is greater than or equal to one, and an area of at least one thermally conductive plate is larger than an area of the DSP chip 302, so as to improve heat dissipation efficiency of the thermally conductive plate.

In some embodiments, the fifth thermally conductive via hole in the circuit board 300 includes a first sub-thermally conductive via hole 313 and a second sub-thermally conductive via hole 314, where the first sub-thermally conductive via hole 313 runs through the upper layer board 303 and the first thermally conductive plate 304, and two ends of the first sub-thermally conductive via hole 313 are respectively connected to the ground solder balls 3021 of the DSP chip 302 and the first thermally conductive plate 304, so as to transfer the heat from the DSP chip 302 to the first thermally conductive plate 304 through the first sub-thermally conductive via hole 313.

The second sub-thermally conductive via hole 314 runs through the upper layer board 303 and the second thermally conductive plate 305, and two ends of the second sub-thermally conductive via hole 314 are respectively connected to the ground solder balls of the DSP chip 302 and the second thermally conductive plate 305, so as to transfer the heat from the DSP chip 302 to the second thermally conductive plate 305 through the second sub-thermally conductive via hole 314.

In some embodiments, the first thermally conductive via hole 307 and the first sub-thermally conductive via hole 313 may be thermally conductive via holes at the same position, and the second thermally conductive via hole 308 and the second sub-thermally conductive via hole 314 may be the same thermally conductive via hole; or, the first thermally conductive via hole 307 and the first sub-thermally conductive via hole 313 may be thermally conductive via holes at different positions, and the second thermally conductive via hole 308 and the second sub-thermally conductive via hole 314 may be thermally conductive via holes at different positions.

When the inner layer of the circuit board 300 includes a first thermally conductive plate 304 and a second thermally conductive plate 305, the sixth thermally conductive via hole connecting the ground gold fingers on the upper layer board 303 to the thermally conductive plate includes a third sub-thermally conductive via hole 315 and a fourth sub-thermally conductive via hole 316, where the third sub-thermally conductive via hole 315 runs through the ground gold fingers and the first thermally conductive plate 304, two ends of the third sub-thermally conductive via hole 315 are respectively connected to the ground gold fingers and the first thermally conductive plate 304, so as to transfer the heat from the first thermally conductive plate 304 to the ground gold fingers on the upper layer board 303 through the third sub-thermally conductive via hole 315.

The fourth sub-thermally conductive via hole 316 runs through the ground gold fingers and the second thermally conductive plate 305, and two ends of the fourth sub-thermally conductive via hole 316 are respectively connected to the ground gold fingers and the second thermally conductive plate 305, so as to transfer the heat from the second thermally conductive plate 305 to the ground gold fingers on the upper layer board 303 through the fourth sub-thermally conductive via hole 316.

The heat from the DSP chip 302 is transferred to the first thermally conductive plate 304 through the first sub-thermally conductive via hole 313, and the heat from the first thermally conductive plate 304 is transferred to the ground gold fingers on the upper layer board 303 through the third sub-thermally conductive via hole 315. The heat from the DSP chip 302 is transferred to the second thermally conductive plate 305 through the second sub-thermally conductive via hole 314, and the heat from the second thermally conductive plate 305 is transferred to the ground gold fingers on the upper layer board 303 through the fourth sub-thermally conductive via hole 316. When the optical module is inserted into a cage of a host computer, the ground gold fingers of the optical module are connected to an electrical connector of the host computer. The ground gold fingers transfer heat to the electrical connector, and the heat is then dissipated through the electrical connector, thereby improving heat dissipation efficiency of the optical module.

In some embodiments, in order to improve heat dissipation efficiency, multiple rows of ground gold fingers can be arranged on the upper layer board 303, thereby adding heat dissipation channels in the circuit board 300.

The upper layer board 303 is provided with a first row of ground gold fingers 3011 and a second row of ground gold fingers 3012, where the second row of ground gold fingers 3012 is located at the end of the upper layer board 303, and the first row of ground gold fingers 3011 is located between the DSP chip 302 and the second row of ground gold fingers 3012.

The first row of ground gold fingers 3011 can be connected to the first thermally conductive plate 304 through the third sub-thermally conductive via hole 315 and can be connected to the second thermally conductive plate 305 through the fourth sub-thermally conductive via hole 316, so as to achieve heat transfer among the first thermally conductive plate 304, the second thermally conductive plate 305, and the first row of ground gold fingers 3011.

In some embodiments, a seventh thermally conductive via hole is provided between the second row of ground gold fingers 3012 and the thermally conductive plate in the circuit board 300, where two ends of one sub-thermally conductive via hole of the seventh thermally conductive via hole are respectively connected to the second row of ground gold fingers 3012 and the first thermally conductive plate 304; and two ends of another sub-thermally conductive via hole of the seventh thermally conductive via hole are respectively connected to the second row of ground gold fingers 3012 and the second thermally conductive plate 305. In this way, heat transfer is achieved among the first thermally conductive plate 304, the second thermally conductive plate 305, and the second row of ground gold fingers 3012.

In some embodiments, the heat from the first thermally conductive plate 304 is transferred to the two rows of ground gold fingers on the upper layer board 303 through the third sub-thermally conductive via hole 315 and one sub-thermally conductive via hole of the seventh thermally conductive via hole, and the heat from the second thermally conductive plate 305 is transferred to the two rows of ground gold fingers on the upper layer board 303 through the fourth sub-thermally conductive via hole 316 and another sub-thermally conductive via hole of the seventh thermally conductive via hole, such that heat dissipation channels are added in the circuit board 300, thereby improving heat dissipation efficiency.

In some embodiments, in order to improve heat dissipation efficiency, multiple rows of ground gold fingers can also be arranged on the lower layer board 306, thereby adding heat dissipation channels in the circuit board 300.

The lower layer board 306 is provided with a third row of ground gold fingers 3013 and a fourth row of ground gold fingers 3014, where the fourth row of ground gold fingers 3014 is located at the end of the lower layer board 306, and the third row of ground gold fingers 3013 is located between the DSP chip 302 and the fourth row of ground gold fingers 3014.

An eighth thermally conductive via hole is provided between the third row of ground gold fingers 3013 and the thermally conductive plate, where two ends of the eighth thermally conductive via hole are respectively connected to the third row of ground gold fingers 3013 and the thermally conductive plate; and a ninth thermally conductive via hole is provided between the fourth row of ground gold fingers 3014 and the thermally conductive plate, where two ends of the ninth thermally conductive via hole are respectively connected to the fourth row of ground gold fingers 3014 and the thermally conductive plate.

When the inner layer of the circuit board 300 includes a first thermally conductive plate 304 and a second thermally conductive plate 305, two ends of one sub-thermally conductive via hole of the eighth thermally conductive via hole are respectively connected to the third row of ground gold fingers 3013 and the second thermally conductive plate 305, and two ends of another sub-thermally conductive via hole of the eighth thermally conductive via hole are respectively connected to the third row of ground gold fingers 3013 and the first thermally conductive plate 304, so as to achieve heat transfer among the first thermally conductive plate 304, the second thermally conductive plate 305, and the third row of ground gold fingers 3013.

The ninth thermally conductive via hole includes a fifth sub-thermally conductive via hole 317 and a sixth sub-thermally conductive via hole 318, where two ends of the fifth sub-thermally conductive via hole 317 are respectively connected to the fourth row of ground gold fingers 3014 and the second thermally conductive plate 305, and two ends of the sixth sub-thermally conductive via hole 318 are respectively connected to the fourth row of ground gold fingers 3014 and the first thermally conductive plate 304, so as to achieve heat transfer among the first thermally conductive plate 304, the second thermally conductive plate 305, and the fourth row of ground gold fingers 3014.

In some embodiments, the heat from the first thermally conductive plate 304 is transferred to the ground gold fingers on the lower layer board 306 through another sub-thermally conductive via hole of the eighth thermally conductive via hole and the sixth sub-thermally conductive via hole 318, and the heat from the second thermally conductive plate 305 is transferred to the ground gold fingers on the lower layer board 306 through one sub-thermally conductive via hole of the eighth thermally conductive via hole and the fifth sub-thermally conductive via hole 317, such that heat dissipation channels are added in the circuit board 300, thereby improving heat dissipation efficiency.

FIG. 14 is a fifth partial assembly cross-sectional view of a circuit board and a digital signal processor in an optical module according to some embodiments of the present disclosure. As shown in FIG. 14, when the thermally conductive block 311 is embedded in the inner layer of the circuit board 300, the ground solder balls of the DSP chip 302 are connected to the thermally conductive block 311 through the third thermally conductive via hole 309, and the side of the thermally conductive block 311 contacts the first thermally conductive plate 304 and the second thermally conductive plate 305, such that the heat from the DSP chip 302 is quickly transferred to the first thermally conductive plate 304 and the second thermally conductive plate 305 through the thermally conductive block 311, thereby improving heat dissipation efficiency.

The heat from the first thermally conductive plate 304 is transferred to the first row of ground gold fingers 3011 on the upper layer board 303 through the third sub-thermally conductive via hole 315 and is transferred to the second row of ground gold fingers 3012 on the upper layer board 303 through one sub-thermally conductive via hole of the seventh thermally conductive via hole; and the heat from the second thermally conductive plate 305 is transferred to the first row of ground gold fingers 3011 on the upper layer board 303 through the fourth sub-thermally conductive via hole 316 and is transferred to the second row of ground gold fingers 3012 on the upper layer board 303 through another sub-thermally conductive via hole of the seventh thermally conductive via hole, thereby achieving heat transfer among the first thermally conductive plate 304, the second thermally conductive plate 305, and the ground gold fingers on the upper layer board 303.

The heat from the first thermally conductive plate 304 is transferred to the third row of ground gold fingers 3013 on the lower layer board 306 through another sub-thermally conductive via hole of the eighth thermally conductive via hole and is transferred to the fourth row of ground gold fingers 3014 on the lower layer board 306 through the sixth sub-thermally conductive via hole 318; and the heat from the second thermally conductive plate 305 is transferred to the third row of ground gold fingers 3013 on the lower layer board 306 through one sub-thermally conductive via hole of the eighth thermally conductive via hole and is transferred to the fourth row of ground gold fingers 3014 on the lower layer board 306 through the fifth sub-thermally conductive via hole 317, thereby achieving heat transfer among the first thermally conductive plate 304, the second thermally conductive plate 305, and the ground gold fingers on the lower layer board 306.

In some embodiments, when the heat from the DSP chip 302 is transferred to the ground gold fingers on the surface of the circuit board 300 through the thermally conductive plate in the inner layer of the circuit board 300, the heat from the DSP chip 302 can also be dissipated in an auxiliary manner via the electrical connection between the DSP chip 302 and the power gold fingers on the circuit board 300, thereby improving heat dissipation efficiency.

In the optical module provided by the present disclosure, there are two heat dissipation paths for the heat from the DSP chip 302. One is that the ground solder balls 3021 of the DSP chip 302 are connected to the thermally conductive plate in the inner layer of the circuit board 300 through the thermally conductive via hole, and the thermally conductive plate is connected to the ground gold fingers on the surface of the circuit board 300 through the thermally conductive via hole, such that the heat from the DSP chip 302 is transferred to the ground gold fingers on the surface of the circuit board 300 through the thermally conductive plate in the inner layer of the circuit board 300, while the solder balls with other attributes of the DSP chip 302 provide auxiliary heat dissipation. The other is that the power solder balls 3022 of the DSP chip 302 are electrically connected to the power wiring on the thermally conductive plate in the inner layer of the circuit board 300 through the via hole, and the power wiring is electrically connected to the power gold fingers on the upper layer board 303 and/or the lower layer board 306 of the circuit board 300 through the via hole, such that the heat is transferred during electrical signal transmission, thereby achieving the electrical and thermal multiplexing effect, while the solder balls with other attributes of the DSP chip 302 provide auxiliary heat dissipation.

Both of the heat dissipation methods above can achieve heat transfer to the ground gold fingers and/or the power gold fingers on the surface of the circuit board 300 in the same or different layers of the circuit board 300, thereby greatly improving heat dissipation efficiency of the DSP chip 302.

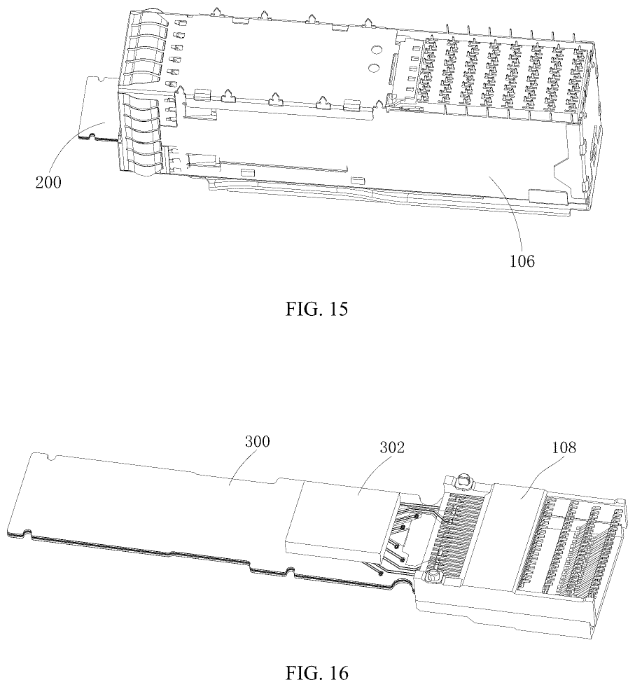

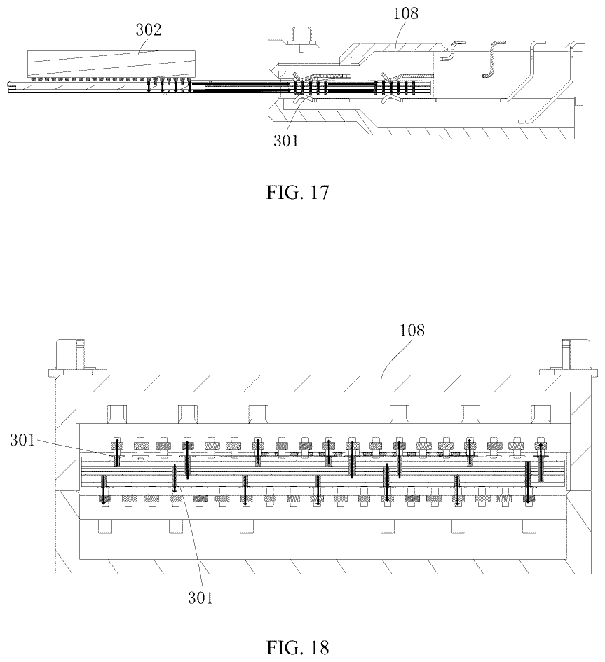

FIG. 15 is a schematic assembly diagram of an optical module and a cage of a host computer according to some embodiments of the present disclosure. FIG. 16 is a schematic assembly diagram of a circuit board and an electrical connector in an optical module according to some embodiments of the present disclosure. FIG. 17 is an assembly cross-sectional view of a circuit board and an electrical connector in an optical module according to some embodiments of the present disclosure. FIG. 18 is an assembly cross-sectional view, from another perspective, of a circuit board and an electrical connector in an optical module according to some embodiments of the present disclosure. As shown in FIG. 15 to FIG. 18, the heat from the DSP chip 302 is transferred to the thermally conductive plate in the inner layer of the circuit board 300 through the thermally conductive via hole in the circuit board 300, and the thermally conductive plate transfers the heat to the ground gold fingers and the power gold fingers on the surface of the circuit board 300 through the via holes in the circuit board 300. When the optical module 200 is inserted into the cage 106 of the host computer, the ground gold fingers and the power gold fingers of the optical module 200 are electrically connected to the electrical connector 108 of the host computer, such that the heat from the ground gold fingers and the power gold fingers can be transferred to the electrical connector 108. The heat from the electrical connector 108 is dissipated by a heat sink in the host computer, thereby greatly improving heat dissipation efficiency of the optical module.

In the optical module provided by the embodiments of the present disclosure, the heat from the DSP chip with the highest power consumption is directly transferred to the gold fingers on the surface of the circuit board through the thermally conductive layer on the surface of the circuit board, the ground solder balls of the DSP chip transfer the heat to the thermally conductive plate in the circuit board through the thermally conductive via hole in the circuit board, and the heat from the thermally conductive plate is transferred to the ground gold fingers on the surface of the circuit board through the thermally conductive via hole; and the power solder balls of the DSP chip are connected to the power wiring on the thermally conductive plate in the inner layer of the circuit board through the via hole, and the power wiring is electrically connected to the power gold fingers on the circuit board through the via hole, thereby achieving the electrical and thermal multiplexing effect. When the optical module is inserted into the host computer, the gold fingers of the optical module are connected to the electrical connector of the host computer, and the heat from the DSP chip is transferred to the electrical connector through the circuit board, thereby greatly improving heat dissipation efficiency of the optical module.

Finally, it should be noted that the above embodiments are provided merely to illustrate the technical solutions of the present disclosure and not to limit them. Although the present disclosure has been described in detail with reference to the aforementioned embodiments, those of ordinary skill in the art should understand that they can still make modifications on the technical solutions described in the aforementioned embodiments or make equivalent replacements on some of the technical features; and these modifications or replacements do not make the essence of the corresponding technical solutions depart from the spirit and scope of the technical solutions of the various embodiments of the present disclosure.

1. An optical module, comprising:
a lower shell part comprising a bottom plate and two lower side plates, the two lower side plates being connected to respective opposing sides of the bottom plate;
a circuit board that is mounted in the lower shell part, two opposite sides of the circuit board respectively contacting the two lower side plates;
a digital signal processor that is electrically connected to the circuit board via solder balls arranged in a rectangular array, the solder balls comprising ground solder balls and power solder balls;
wherein the circuit board comprises:
an upper layer board, wherein a thermally conductive layer is plated on the upper layer board, the thermally conductive layer contacting the lower side plates, and ground solder balls located at an edge of the digital signal processor being connected to the thermally conductive layer; and a thermally conductive connecting block is disposed in the upper layer board, ground solder balls located at an inner side of the digital signal processor being electrically connected to the ground solder balls located at the edge of the digital signal processor through the thermally conductive connecting block, and the thermally conductive connecting block not extending across entire solder ball region of the digital signal processor;
a lower layer board that is stacked with the upper layer board; and
at least one thermally conductive plate that is arranged between the upper layer board and the lower layer board, an area of the at least one thermally conductive plate being larger than an area of the digital signal processor, and a side of the at least one thermally conductive plate contacting corresponding lower side plate;
wherein a thermally conductive via hole is provided between the upper layer board and the at least one thermally conductive plate, two ends of the thermally conductive via hole being respectively connected to the ground solder balls and the at least one thermally conductive plate, such that heat from the digital signal processor is conducted to the at least one thermally conductive plate through the thermally conductive via hole.

2. The optical module according to claim 1, wherein the circuit board comprises a first thermally conductive plate and a second thermally conductive plate arranged in a stacked manner, wherein
the first thermally conductive plate is located between the upper layer board and the lower layer board, the second thermally conductive plate is located between the first thermally conductive plate and the lower layer board, and sides of the first thermally conductive plate and/or the second thermally conductive plate contact the lower side plates; and
a first thermally conductive via hole is provided between the upper layer board and the first thermally conductive plate, two ends of the first thermally conductive via hole being respectively connected to the ground solder balls and the first thermally conductive plate; and a second thermally conductive via hole is provided between the upper layer board and the second thermally conductive plate, two ends of the second thermally conductive via hole being respectively connected to the ground solder balls and the second thermally conductive plate.

3. The optical module according to claim 2, wherein a thermally conductive block is arranged between the upper layer board and the second thermally conductive plate, the thermally conductive block being in contact with both the first thermally conductive plate and the second thermally conductive plate, and an area of the thermally conductive block being larger than the area of the digital signal processor;
a third thermally conductive via hole is provided between the upper layer board and the thermally conductive block, two ends of the third thermally conductive being respectively connected to the ground solder balls and the thermally conductive block, other types of solder balls of the digital signal processor not being connected to the thermally conductive block.

4. The optical module according to claim 3, wherein a fourth thermally conductive via hole is provided between bottom surfaces of the thermally conductive block and the second thermally conductive plate, two ends of the fourth thermally conductive via hole being respectively connected to the thermally conductive block and the second thermally conductive plate.

5. The optical module according to claim 1, wherein the two opposite sides of the circuit board are plated with metal layers, the metal layers contacting the lower side plates, and gaps existing between the metal layers and the thermally conductive plate in the circuit board.

6. The optical module according to claim 1, wherein the two opposite sides of the circuit board are provided with thermally conductive pads, the thermally conductive pads being in contact with the lower side plates, and the thermally conductive pads being electrically insulating.

7. The optical module according to claim 6, wherein a thickness of the thermally conductive pad is 2 to 10 mm.

8. The optical module according to claim 2, wherein a via hole is provided between the upper layer board and the at least one thermally conductive plate, one end of the via hole being electrically connected to the power solder balls; the at least one thermally conductive plate is provided thereon with a clearance groove, the clearance groove accommodating a power wiring, and the power wiring being electrically connected to the other end of the via hole;
one end of the upper layer board is provided thereon with power gold fingers, and via holes are provided between the power gold fingers and the at least one thermally conductive plate, two ends of the via holes being respectively electrically connected to the power wiring and the power gold fingers.

9. The optical module according to claim 8, wherein a first via hole is provided between the upper layer board and the first thermally conductive plate, two ends of the first via hole being respectively electrically connected to the power solder balls and power wiring on the first thermally conductive plate;
a second via hole is provided between the upper layer board and the second thermally conductive plate, two ends of the second via hole being respectively electrically connected to the power solder balls and power wiring on the second thermally conductive plate.

10. The optical module according to claim 8, wherein the power gold fingers on the upper layer board comprise a first row of power gold fingers and a second row of power gold fingers, the second row of power gold fingers being located at an edge of the upper layer board, the first row of power gold fingers being located between the second row of power gold fingers and the digital signal processor;
a third via hole is provided between the first row of power gold fingers and the at least one thermally conductive plate, two ends of the third via hole being respectively electrically connected to power wiring on the at least one thermally conductive plate and the first row of power gold fingers;
a fourth via hole is provided between the second row of power gold fingers and the at least one thermally conductive plate, two ends of the fourth via holes being respectively electrically connected to power wiring on the at least one thermally conductive plate and the second row of power gold fingers.

11. The optical module according to claim 8, wherein the lower layer board of the circuit board is provided thereon with a third row of power gold fingers and a fourth row of power gold fingers, the fourth row of power gold fingers being located at an end of the lower layer board, the third row of power gold fingers being located between the digital signal processor and the fourth row of power gold fingers;
a fifth via hole is provided between the third row of power gold fingers and the at least one thermally conductive plate, the third row of power gold fingers being electrically connected to power wiring on the at least one thermally conductive plate through the fifth via hole; and
a sixth via hole is provided between the fourth row of power gold fingers and the at least one thermally conductive plate, the fourth row of power gold fingers being electrically connected to power wiring on the at least one thermally conductive plate through the sixth via hole.

12. An optical module, comprising:
a lower shell part, the lower shell part comprising a bottom plate and two lower side plates, the two lower side plates being connected to respective opposing sides of the bottom plate;
a circuit board that is mounted in the lower shell part, two opposite sides of the circuit board respectively contacting the two lower side plates;
a digital signal processor that is electrically connected to the circuit board through solder balls arranged in a rectangular array, the solder balls comprising ground solder balls and power solder balls;
wherein the circuit board comprises:
an upper layer board, wherein a thermally conductive layer is plated on a surface of the upper layer board, the thermally conductive layer contacting the lower side plates, ground solder balls located at an edge of the digital signal processor being connected to the thermally conductive layer; and a ground gold finger is provided at one end of the upper layer board, the thermally conductive layer being connected to the ground gold finger;
a lower layer board that is stacked with the upper layer board; and
at least one thermally conductive plate that is located between the upper layer board and the lower layer board, wherein a side of the at least one thermally conductive plate contacts corresponding lower side plate; a fifth thermally conductive via hole is provided between the upper layer board and the at least one thermally conductive plate, two ends of the fifth thermally conductive via hole being respectively connected to the ground solder balls and the at least one thermally conductive plate such that heat from the digital signal processor is conducted through the fifth thermally conductive via hole to the at least one thermally conductive plate; and a sixth thermally conductive via hole is provided between the at least one thermally conductive plate and the ground gold finger, two ends of the sixth thermally conductive via hole being respectively connected to the at least one thermally conductive plate and the ground gold finger such that heat from the at least one thermally conductive plate is conducted through the sixth thermally conductive via hole to the ground gold finger.

13. The optical module according to claim 12, wherein the circuit board comprises a first thermally conductive plate and a second thermally conductive plate arranged in a stacked manner, the first thermally conductive plate being located between the upper layer board and the lower layer board, the second thermally conductive plate being located between the first thermally conductive plate and the lower layer board, and a side of the first thermally conductive plate and/or the second thermally conductive plate contacting corresponding lower side plate;
the fifth thermally conductive via hole comprise a first sub-thermally conductive via hole and a second sub-thermally conductive via hole, wherein the first sub-thermally conductive via hole runs through the upper layer board and the first thermally conductive plate, two ends of the first sub-thermally conductive via hole being respectively connected to the ground solder ball and the first thermally conductive plate; and the second sub-thermally conductive via hole runs through the upper layer board and the second thermally conductive plate, and two ends of the second sub-thermally conductive via hole being respectively connected to the ground solder ball and the second thermally conductive plate.

14. The optical module according to claim 13, wherein the sixth thermally conductive via hole comprises a third sub-thermally conductive via hole and a fourth sub-thermally conductive via hole, wherein the third sub-thermally conductive via hole runs through the ground gold finger and the first thermally conductive plate, two ends of the third sub-thermally conductive via hole being respectively connected to the ground gold finger and the first thermally conductive plate; and the fourth sub-thermally conductive via hole runs through the ground gold finger and the second thermally conductive plate, two ends of the fourth sub-thermally conductive via hole being respectively connected to the ground gold finger and the second thermally conductive plate.

15. The optical module according to claim 14, wherein the upper layer board of the circuit board is provided thereon with a first row of ground gold fingers and a second row of ground gold fingers, wherein the second row of ground gold fingers is located at an end of the upper layer board, the first row of ground gold fingers is located between the digital signal processor and the second row of ground gold fingers;
the first row of ground gold fingers is connected to the first thermally conductive plate through the third sub-thermally conductive via hole, and is connected to the second thermally conductive plate through the fourth sub-thermally conductive via hole;
a seventh thermally conductive via hole is provided between the second row of ground gold fingers and the thermally conductive plate in the circuit board, two ends of one sub-thermally conductive via hole of the seventh thermally conductive via hole are respectively connected to the second row of ground gold fingers and the first thermally conductive plate, and two ends of another sub-thermally conductive via hole of the seventh thermally conductive via hole are respectively connected to the second row of ground gold fingers and the second thermally conductive plate.

16. The optical module according to claim 12, wherein the lower layer board of the circuit board is provided thereon with a third row of ground gold fingers and a fourth row of ground gold fingers, wherein the fourth row of ground gold fingers is located at an end of the lower layer board, the third row of ground gold fingers is located between the digital signal processor and the fourth row of ground gold fingers;
an eighth thermally conductive via hole is provided between the third row of ground gold fingers and the at least one thermally conductive plate, two ends of the eighth thermally conductive via hole being respectively connected to the third row of ground gold fingers and the at least one thermally conductive plate; and a ninth thermally conductive via hole is provided between the fourth row of ground gold fingers and the at least one thermally conductive plate, two ends of the ninth thermally conductive via holes being respectively connected to the fourth row of ground gold fingers and the at least one thermally conductive plate.

17. The optical module according to claim 12, wherein a via hole is provided between the upper layer board and the at least one thermally conductive plate, one end of the via hole being electrically connected to the power solder balls; the at least one thermally conductive plate is provided thereon with a clearance groove, the clearance groove accommodating a power wiring, and the power wiring being electrically connected to the other end of the via hole;
one end of the upper layer board is provided thereon with power gold fingers, and via holes are provided between the power gold fingers and the at least one thermally conductive plate, two ends of the via holes being respectively electrically connected to the power wiring and the power gold fingers.

18. The optical module according to claim 17, wherein a first via hole is provided between the upper layer board and the first thermally conductive plate, two ends of the first via hole being respectively electrically connected to the power solder balls and power wiring on the first thermally conductive plate;
a second via hole is provided between the upper layer board and the second thermally conductive plate, two ends of the second via hole being respectively electrically connected to the power solder balls and power wiring on the second thermally conductive plate.

19. The optical module according to claim 17, wherein the power gold fingers on the upper layer board comprise a first row of power gold fingers and a second row of power gold fingers, the second row of power gold fingers being located at an edge of the upper layer board, the first row of power gold fingers being located between the second row of power gold fingers and the digital signal processor;
a third via hole is provided between the first row of power gold fingers and the at least one thermally conductive plate, two ends of the third via hole being respectively electrically connected to power wiring on the at least one thermally conductive plate and the first row of power gold fingers;
a fourth via hole is provided between the second row of power gold fingers and the at least one thermally conductive plate, two ends of the fourth via holes being respectively electrically connected to power wiring on the at least one thermally conductive plate and the second row of power gold fingers.

20. The optical module according to claim 17, wherein the lower layer board of the circuit board is provided thereon with a third row of power gold fingers and a fourth row of power gold fingers, the fourth row of power gold fingers being located at an end of the lower layer board, the third row of power gold fingers being located between the digital signal processor and the fourth row of power gold fingers;
a fifth via hole is provided between the third row of power gold fingers and the at least one thermally conductive plate, the third row of power gold fingers being electrically connected to power wiring on the at least one thermally conductive plate through the fifth via hole; and
a sixth via hole is provided between the fourth row of power gold fingers and the at least one thermally conductive plate, the fourth row of power gold fingers being electrically connected to power wiring on the at least one thermally conductive plate through the sixth via hole.
